(19) United States
(12) Patent Application Publication
(10) Pub. No.: US 2006/0124973 A1
(43) Pub. Date: Jun. 15, 2006

(54) Energy storage device, module thereof and electric vehicle using the same

(76) Inventors: Juichi Arai, Shirosato (JP); Yoshiaki Kumashiro, Mito (JP); Masanori Yoshikawa, Hitachinaka (JP); Mituru Kobayashi, Hitachiota (JP); Takahiro Yamaki, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/299,742

(22) Filed: Dec. 13, 2005

(30) Foreign Application Priority Data
Dec. 14, 2004 (JP) 2004-360659

(51) Int. Cl. H01L 27/148

(52) U.S. Cl. 257/223

(57) ABSTRACT

An object of the present invention is to provide an energy storage device excellent in input/output characteristics at low temperatures, a module thereof and a vehicle using the module. The present invention provides an energy storage device comprising: a positive electrode having a region where a reaction accompanied by charge exchange occurs; a negative electrode having a region where a reaction accompanied by charge exchange occurs; a separator electrically separating the positive and negative electrodes and allowing mobile ions to pass therethrough; an electrolytic solution having an aprotic nonaqueous solvent comprising the mobile ions; and a region in at least one of the positive and negative electrodes where a charge adsorbing/desorbing reaction occurs.

### FIELD OF THE INVENTION

The present invention relates to a new energy storage device for storing/releasing electric energy, a module thereof and an electric vehicle using the module.

### BACKGROUND ART

In these years, power supplies having higher input/output power than hitherto available are required as power supplies for electric vehicles, hybrid vehicles, electric tools or the like, and additionally, power supplies capable of rapidly charging/discharging and having high capacity are required. Particularly, power supplies having small temperature dependence and capable of maintaining input/output characteristics in a manner better than ever, even at low temperatures such as −20° C. or −30° C. are required.

Such requirements as described above have hitherto been dealt with by making higher the performance of secondary batteries being mainly faradic in reaction mechanism such as lithium secondary batteries, nickel-hydrogen batteries, nickel-cadmium batteries and lead batteries, and by using in combination electric double layer capacitors being non4aradic in reaction mechanism and satisfactory, as instantaneous input/output power supplies, in input/output characteristics and in characteristics in low temperature environments.

Also, Patent Document 1 discloses a lithium secondary battery in which an activated carbon to be used as a material for an electric double layer capacitor is mixed in the positive electrode of the lithium secondary battery for the purpose of attaining high energy density, high output density and improvement of low temperature characteristics.

Patent Document 1: JP Patent Publication (Kokai) No. 2002-260634

### SUMMARY OF THE INVENTION

Conventional lithium secondary batteries are poor in charge/discharge characteristics for large current, and have a problem that the input/output characteristics are markedly degraded particularly under low-temperature conditions and the electric double layer capacitors involved are low in energy density.

The present invention provides an energy storage device excellent in input/output characteristics at low temperatures and high in energy density, an module thereof and a vehicle using the module.

The present invention provides an energy storage device comprising: a positive electrode having a region where a reaction accompanied by charge exchange occurs; a negative electrode having a region where a reaction accompanied by charge exchange occurs; a separator electrically separating the positive and negative electrodes and allowing mobile ions to pass therethrough; an electrolytic solution having an aprotic nonaqueous solvent comprising the mobile ions; and a region in at least one of the positive and negative electrodes where a charge adsorbing/desorbing reaction occurs.

It is preferable that the regions where the reactions accompanied by charge exchange occurs are formed in laminated manner in current collectors and the regions where the charge adsorbing/desorbing reactions occur are formed in a laminated manner on the surfaces of the regions where the reactions accompanied by charge exchange occurs. Alternatively, it is preferable that the regions where the reaction accompanied by charge exchange occurs and the regions where the charge adsorbing/desorbing reaction occurs are formed on the surfaces of the current collectors in an alternate manner.

In particular, the present invention provides an energy storage device comprising a positive electrode to store/release electric energy including a region I where a reaction accompanied by charge exchange occurs and a region II where a charge adsorbing/desorbing reaction occurs; a negative electrode to store/release electric energy on the basis of a region I where a reaction accompanied by charge exchange occurs, or on the basis of a region I where a reaction accompanied by charge exchange occurs and a region II where a charge adsorbing/desorbing reaction occurs; a separator electrically separating the positive and negative electrodes and allowing mobile ions to pass therethrough; and an electrolytic solution comprising the mobile ions; wherein the solvent constituting the electrolytic solution is an aprotic nonaqueous solvent.

More specifically, it is preferable that in the energy storage device according to the present invention, the positive electrode layers formed as the positive electrode on both sides of a highly conductive current collector are constituted with the region I belonging to a reaction, to occur through charge exchange, occuluding/releasing lithium as a compound on the basis of the reaction to occur through charge exchange and the region II belonging to a charge adsorbing/desorbing reaction to store electricity through adsorption/desorption based on the electric potential of the anion. The formation of these two regions is compatible with any forms through forming predetermined regions in the states such as a state of being partially mixed with each other, a state of being formed in a manner partitioned into plane sections, and a state of being formed in a manner laminated on the surface of the current collector; no particular constraint is imposed on the formation state, but formation in a laminated manner is preferable. The formation in a laminated manner is such that the region I is formed on the current collector side, and the region II is formed on the surface of the region I thus formed, and the region II of the positive electrode is abutted on the region I or the region II of the negative electrode through the intermediary of a separator.

Examples of the material capable of forming the region I where the reaction accompanied by charge exchange occurs include LiNiₓMn_{y}Co_{z}O₂ (with the proviso that x+y+z=1), a composite oxide comprising Li and one or more transition metals such as Co, Ni, Mn and Fe, and an olivine-structured phosphate compound represented by LiMePO₄ (Me being Fe, Co or Cr). More specifically, LiNi_{1/3}Mn_{1/3}Co_{1/3}O₂, LiNi0.4Mn_{0.3}Co_{0.2}O₂, LiFePO₄, LiCoPO₄, LiCrPO₄ and the like can be used. These compounds are low in electric conductance, and for the purpose of compensating this low conductance, amorphous carbon materials such as graphite carbon powder and acetylene black can also be used as conducting aids in a manner mixed with these compounds.

As the materials to be used in combination for the reaction accompanied by charge exchange, organic conducting materials doped with alkali metals, alkali earth metals, onium ions, phosphonium ions or acetylcholin can be used. Examples of the usable organic conductors include polypyrrole, polythiophene, polyacetylene, TTF(tetrathiafulvalene)-TCNQ(tetracyanoquinodimethane) complex, polyisonaphthothiophene, polyparaphenylene, polyparaphenylenevinylene and polythiophenevinylene.

As the material applicable to the region II where the charge adsorbing/desorbing reaction occurs, activated carbon and carbon nanotube can be used. Preferable is an activated carbon suitably having a particle size of 1 to 100 μm, a specific surface area of 1000 to 3000 m²/g, pores called micropores of 0.002 μm or less in diameter, pores called mesopores of 0.002 to 0.05 μm in diameter and pores called macropores of 0.05 μm or more in diameter.

The positive electrode composed of the current collector and the positive electrode layers is made to face the separator having a large number of pores to hold the electrolytic solution and to allow mobile ions to permeate therethrough, and is further made to face the negative electrode through the intermediary of the separator.

The negative electrode is composed of a highly conductive metal current collector and negative electrode layers formed on both sides of the current collector. The negative electrode is constituted with the region I belonging to the reaction to occur through charge exchange, or with the region I belonging to the reaction to occur through charge exchange and the region II belonging to the charge adsorbing/desorbing reaction. Examples of materials usable as the materials belonging to the charge donating/accepting reaction include lithium metal, a lithium alloy, silicon, silicon oxides, tin, tin oxides, and composite materials composed of a carbonaceous material and one or more of lithium metal, a lithium alloy, silicon, silicon oxides, tin and tin oxides. Examples of materials usable as the materials belonging to the charge adsorbing/desorbing reaction include activated carbon and carbon nanotube. Alkali- or steam-treated products of expanded graphite and amorphous carbon capable of allowing both of these reactions to occur in a concerted manner can also be used.

These electrodes each are prepared by being applied as a paste containing a binder to be formed on both sides of the current collector, then dried, pressed and heated. As the binder, polyvinylidene fluoride, polytetrafluoroethylene, polyvinyl alcohol derivatives, styrenebutadiene rubber and the like can be used.

To the positive and negative electrodes prepared as described above, metal foil tabs made of nickel or the like are welded, the positive and negative electrodes being connected to the battery can and the battery lid through these tabs. The connection of the positive and negative electrodes to the battery can or the battery lid is optional. It is to be noted that when the battery can is made of aluminum, the positive electrode is preferably connected to the battery can. A packing is an insulator serving to make the polarities of the battery can and the battery lid independent of each other, and also has a function to maintain the internal airtightness. As the packing, molded articles made of rubber or fluororubber can be used. For the insulators to protect the connection between the battery tabs and the battery can and the connection between the battery tabs and the battery lid, polyimide film or the like can be used. The battery is fabricated in such a way that the electrolytic solution is injected and then the positive electrode lid and the battery can are crimped to each other to seal the battery.

For the electrolytic solution, the nonaqueous solvents represented by formulas (1) to (20) can be used as admixtures.

Examples of the compounds represented by formula (1) include ethylene carbonate, propylene carbonate, butylene carbonate, trifluoroethylene carbonate, chloroethylene carbonate, fluoroethylene carbonate, difluoroethylene carbonate and vinylethylene carbonate.

Examples of the compounds represented by formula (2) include dimethyl carbonate, ethyl methyl carbonate, diethyl carbonate, methyl propyl carbonate, ethyl propyl carbonate, dipropyl carbonate, trifluoromethyl methyl carbonate and trifluoroethyl methyl carbonate.

Examples of the compounds represented by formula (3) include methyl formate, ethyl formate, propyl formate, methyl acetate, ethyl acetate, propyl acetate, methyl propionate, ethyl propionate and propyl propionate.

Examples of the compounds represented by formula (4) include γ-butylolactone, α-bromo-γ-butylolactone, α-methyl-γ-butylolactone, α-fluoro-γ-butylolactone, α-chloro-γ-butylolactone, α-methoxy-γ-butylolactone, α-acetyl-γ-butylolactone, β-fluoro-γ-butylolactone and γ-fluoro-γ-butylolactone.

Examples of the compounds represented by formula (5) include 1,3-dioxolane, 2-methyl-1,3-dioxolane, 2,2-dimethyl-1,3-dioxolane, 4-methyl-1,3-dioxolane and 4,4-dimethyl-1,3-dioxolane.

Examples of the compounds represented by formula (6) include monoglyme, diglyme and triglyme, and examples of the compounds represented by formula (7) include tetrahydrofuran, 1-ethyl-tetrahydrofuran, 2-methyl-tetrahydrofuran, and 2,3-dimethyl-tetrahydrofuran.

Examples of the compounds represented by formula (8) include methyl nonafluorobutyl ether, ethyl nonafluorobutyl ether, dimethyl ether and diethyl ether, and examples of the compounds represented by formula (9) include 1,1,2,2,3,3,4-heptafluorocyclopentane, cyclopentane and methoxycyclopentane.

Examples of the compounds represented by formula (10) include trifluoromethylheptane, butyl iodide and pentafluoroethylheptane, and examples of the compounds represented by formula (11) include vinylene carbonate, methylvinylene carbonate, dimethyl vinylene carbonate and ethylvinylene carbonate.

Examples of the compounds represented by formula (12) include biphenyl, terphenyl and p-dimethylbiphenyl, and examples of the compounds represented by formula (13) include ethylene sulfide, methylethylene sulfide, dimethylethylene sulfide and ethylmethylethylene sulfide.

Examples of the compounds represented by formula (14) include propane sultone, 3-methyl-propane sultone, 4-methyl-propane sultone, 5-methyl-propane sultone, 3-fluoro-propane sultone and 4-fluoro-propane sultone, and examples of the compounds represented by formula (15) include diphenyl disulfide, p-dimethyl disulfide, bisdiethylthiocarbomyl disulfide and diallyl disulfide.

Examples of the compounds represented by formula (16) include methoxy benzene, dimethoxy benzenes, fluorobenzene, difluorobenzenes and methylmethoxybenzenes, and examples of the compounds represented by formula (17) include o-methoxypyridine, m-methoxypyridine, p-methoxypyridine, o-ethoxypyridine, m-ethoxypyridine and p-ethoxypyridine.

Examples of the compounds represented by formula (18) include hexamethoxytriphosphazene, hexaethoxytriphosphazene and hexapropoxytriphosphazene, and examples of the compounds represented by formula (19) include hexamethoxycyclotriphosphazene, hexaethoxycyclotriphosphazene and hexapropoxycyclotriphosphazene.

Examples of the compounds represented by formula (20) include trimethyl phosphate, triethyl phosphate and tripropyl phosphate.

As the electrolyte salts, the following salts can be used each alone or as admixtures of two or more thereof: LiPF₆, LiAsF₆, LiBF₄, LiSO₂CF₃, LiN[SO₂CF₃]₂, LiN[SO₂CF₂CF₃]₂, LiC[SO₂CF₃]₃, LiC[SO₂CF₂CF₃]₂, LiB[OCOCF₃]₄, LiB[OCOCF₂CF₃]₄, LiI, LiBr, LiCl, NaPF₆, NaAsF₆, NaBF₄, NaSO₂CF₃, NaN[SO₂CF₃]₂, NaN[SO₂CF₂CF₃]₂, NaC[SO₂CF₃]₃, NaC[SO₂CF₂CF₃]₂, NaB[OCOCF₃]₄, NaB[OCOCF₂CF₃]₄, NaI, NaBr and NaCl.

By mixing an appropriate amount of a polymer resin in an electrolytic solution, the electrolytic solution can be converted into a gelled electrolyte to be used in place of the electrolytic solution. Examples of the polymers to be mixed to prepare the gelled electrolyte include polyethylene oxide (PEO), polymethacrylate (PMMA), polyacrylonitrile (PAN), polyvinylidene fluoride (PVDF) and polyvinylidene fluoride-hexafluoropropylene copolymer (PVDF-HFP).

According to the present invention, a plurality of energy storage devices are connected to form an energy storage device module in which the plurality of energy storage devices are connected (e.g. in series) in compliance with the desired voltages. The voltage detecting units for detecting these individual voltages and the control circuits for controlling the charging and discharging currents flowing in the individual energy storage devices are installed, and the units for sending commands to these units are also installed. The communications between these units are set to be conducted by means of electric signals. At the time of charging, when the voltages of the individual energy storage devices, detected by the voltage detecting units are lower than the preset charging voltages, electric currents are made to flow into the energy storage devices to charge the devices. For the energy storage devices having reached the preset charging voltages, the electric signals from the units for sending commands make the charging currents not flow into the energy storage devices so as to prevent the overcharge thereof.

On the other hand, at the time of discharging, similarly the voltages of the individual energy storage devices are detected by the units for detecting voltage, and when the energy storage devices reach the predetermined discharging voltages, the discharging currents are made not to flow. As for the precision of the voltage detection, the voltage resolution is preferably 0.1 V or less, and more preferably 0.02 V or less. The energy storage device module can be actualized by detecting the voltages of the individual energy storage devices in satisfactory precisions as described above, and by controlling the energy storage devices so as to be operated without undergoing overcharging or overdischarging.

According to the present invention, there can be obtained an energy storage device being excellent in the input/output characteristics at low temperatures and having a high energy density, a module thereof, and an electric vehicle using the module and a hybrid vehicle using the module.

### BRIEF DESCRIPTION OF THE DRAWINGS

FIG. 1 is a partial sectional view of a cylindrical lithium secondary battery as an energy storage device according to the present invention;

FIG. 2 is a graph showing the relationship between the current and the voltage obtained for the lithium secondary battery according to the present invention;

FIG. 3 is a graph showing the relationship between the output power and the battery voltage showing the output characteristics of the lithium secondary battery according to the present invention at −30° C.;

FIG. 4 is an oblique perspective view showing an energy storage device module according to the present invention; and

FIG. 5 is an underside front view of a hybrid electric vehicle using the energy storage device module according to the present invention.

1 . . . current collector (positive electrode)

2 . . . positive electrode layer

3 . . . current collector (negative electrode)

4 . . . negative electrode layers

5 . . . separator

6 . . . negative electrode tab

7 . . . positive electrode tab

8 . . . positive electrode insulator

9 . . . negative electrode insulator

10 . . . battery can

11 . . . battery lid

12 . . . gasket

71 . . . energy storage device

72 . . . container

73 . . . bus bar

74 . . . positive electrode terminal

75 . . . negative electrode terminal

76 . . . module positive electrode terminal

77 . . . control circuit

78 . . . vent hole

79 . . . module negative electrode terminal

81 . . . energy storage device module

82 . . . module control circuit

83 . . . drive motor

84 . . . engine

85 . . . inverter

86 . . . motive power control circuit

87 . . . drive shaft

88 . . . differential gear

89 . . . drive wheel

810 . . . clutch

811 . . . clutch gear

812 . . . speed monitor

### DETAILED DESCRIPTION OF THE PREFERRED EMBODIMENTS

Specific description will be made below with reference to further detailed examples of an energy storage device of the present invention, but the present invention is not limited to the examples to be described below.

### EXAMPLE 1

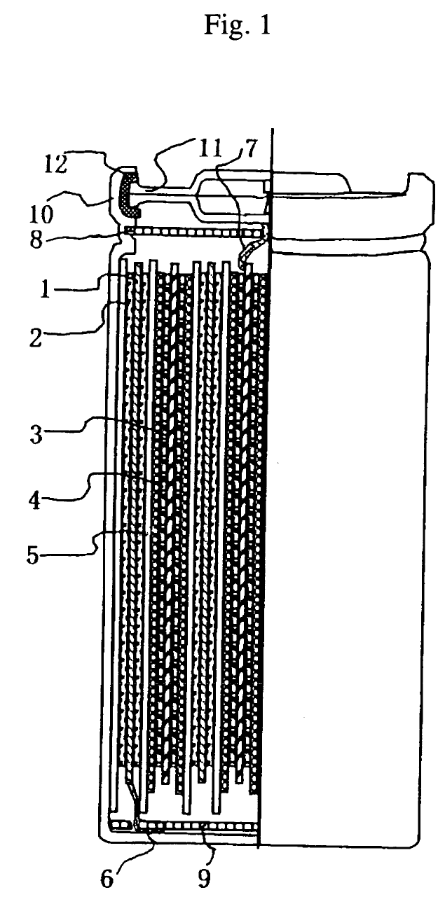

FIG. 1 is a partial sectional view of a cylindrical lithium secondary battery as an energy storage device showing an embodiment of the present invention. Positive electrode layers 2 formed as a positive electrode on both sides of a highly conductive current collector 1 were constituted with a region I belonging to a reaction, to occur through charge exchange, occluding/releasing lithium as a compound on the basis of a reaction to occur through charge exchange, and a region II belonging to a charge adsorbing/desorbing reaction to store electricity through adsorption/desorption based on the electric potential of the anion. The positive electrode composed of the current collector 1 and the positive electrode layers 2 was made to face a separator 5 having a large number of pores to hold an electrolytic solution and to allow mobile ions to permeate therethrough, and was further made to face a negative electrode through the intermediary of the separator 5.

A positive electrode slurry was prepared as follows: as an active material in the region I where the reaction accompanied by charge exchange occurs in the positive electrode, LiNi_{1/3}Mn_{1/3}Co_{1/2}O₂ was used; as a conducting aid, a 4:1 by weight mixture of a graphite carbon having an average particle size of 3 μm and a specific surface area of 13 m²/g and a carbon black having an average particle size of 0.04 μm and a specific surface area of 40 m²/g was used; as a binder, a 8 wt % solution of polyvinylidene fluoride beforehand dissolved in NMP was used; the positive electrode material, the conducting aid and the polyvinylidene fluoride solution were mixed together so as for the ratio between the positive electrode active material, the conducting aid and polyvinylidene fluoride to be 85:10:5; and the mixture was fully kneaded to yield the positive electrode slurry. The both sides of the positive electrode current collector 1 formed of 20 μm thick aluminum foil were coated with the positive slurry and dried. Then, the current collector 1 was pressed with a roll press and further dried to yield an electrode as a positive electrode material having the region I where the reaction accompanied by charge exchange occurs.

Additionally, another slurry was prepared as follows: a 8:1 by weight carbon mixture of an activated carbon having a specific surface area of 2000 m²/g and a carbon black having an average particle size of 0.04 μm and a specific surface area of 40 m²/g was prepared; as a binder, a 8 wt % solution of polyvinylidene fluoride beforehand dissolved in N-methylpyrrolidone was used; the carbon mixture and the binder solution were mixed together so as for the ratio between the activated carbon, the carbon black and polyvinylidene fluoride to be 80:10:10; and the mixture was fully kneaded to yield the slurry. The surface of the above electrode as a positive electrode material was coated with this slurry to form the region II where the charge adsorbing/desorbing reaction occurs, dried and pressed with a press roll to prepare the positive electrode. A positive electrode tab 7 made of nickel foil as a terminal was supersonically welded to one end of the electrode to complete the positive electrode.

A negative electrode comprised a highly conductive metal current collector 3 and negative electrode layers 4 formed on both sides thereof. The negative electrode layers 4 each were constituted with the region I belonging to the reaction to occur through charge exchange, or the region I belonging to the reaction to occur through charge exchange and the region II belonging to the charge adsorbing/desorbing reaction.

As a negative electrode active material, a negative electrode slurry was prepared as follows: a 95:5 by weight carbon mixture was prepared by mechanically mixing an amorphous carbon having an average particle size of 9 μm with a carbon black having an average particle size of 0.04 μm and a specific surface area of 40 m²/g; as a binder, a 8 wt % solution of polyvinylidene fluoride beforehand dissolved in N-methylpyrrolidone was used; the carbon material mixture mixed in advance composed of the amorphous carbon and the carbon black and the binder solution were fully kneaded so as for the ratio between the carbon material mixture and polyvinylidene fluoride to be 90:10 to yield the negative electrode slurry. The both sides of a negative electrode current collector 3 made of a 10 μm thick copper foil were coated with the slurry and dried to form the region I. The member thus formed was pressed with a roll press, and a negative electrode tab 6 made of nickel foil was supersonically welded to an uncoated end of the current collector to prepare the negative electrode. As for the formation of the region II, the region II was able to be formed in the same manner as in the positive electrode layer 2.

An electrode assembly was prepared by winding the positive and negative electrodes prepared as described above in a manner sandwiching therebetween a 30 μm thick finely porous separator 5 having a three-layered structure of PE/PP/PE (polyethylene/polypropylene/polyethylene). The electrode assembly was put in a battery can 10, and then a negative electrode tab 6 was spot welded to the bottom of the battery can 10 to be connected thereto. An electrolytic solution was filled in the battery can 10 from the upper portion thereof, then the battery can 10 and the battery lid 11 were crimped to each other to seal the battery, and thus a lithium secondary battery was fabricated.

The positive electrode tab 7 and the negative electrode tab 6, each made of a metal foil of nickel or the like, were welded to the positive and negative electrodes, respectively, and the positive and negative electrodes were connected to the battery can 10 and the battery lid 11 through these tabs. The connection of the positive and negative electrodes to the battery can 10 or the battery lid 11 is optional. It is to be noted that when the battery can 10 is made of aluminum, the positive electrode is preferably connected to the battery can 10. A packing 12 is an insulator serving to make the polarities of the battery can 10 and the battery lid 11 independent of each other, and also has a function to maintain the internal airtightness. As the packing 12, molded articles made of rubber or fluororubber can be used. For the positive electrode insulator 8 and the negative electrode insulator 9 to respectively protect the connection between the positive electrode tab 7 and the battery can 10 or the battery lid 11 and the connection between the negative electrode tab 6 and the battery can 10 or the battery lid 11, polyimide film or the like can be used.

In present Example 1, as the electrolytic solution, there was used a solution in which the solvent was a 1:2 (EC:EMC) by volume solvent mixture of ethylene carbonate (EC) and ethyl methyl carbonate (EMC), LiPF₆ was dissolved in the mixed solvent in a concentration of 1 mol/dm³ (M), and vinylene carbonate (VC) was further added in a content of 2 wt %.

The lithium secondary battery was charged at a constant current of 200 mA until the battery voltage reached 4.1 V, and then the battery was charged at the constant voltage of 4.1 V until the current value reached 10 mA; after an intermission of 30 min, the battery was discharged at a constant current of 200 mA until the battery voltage reached 2.7 V. This charging-discharging cycle was repeated three times, and the discharge capacity of the third cycle was recorded. The discharge capacity of the lithium secondary battery was 210 mAh.

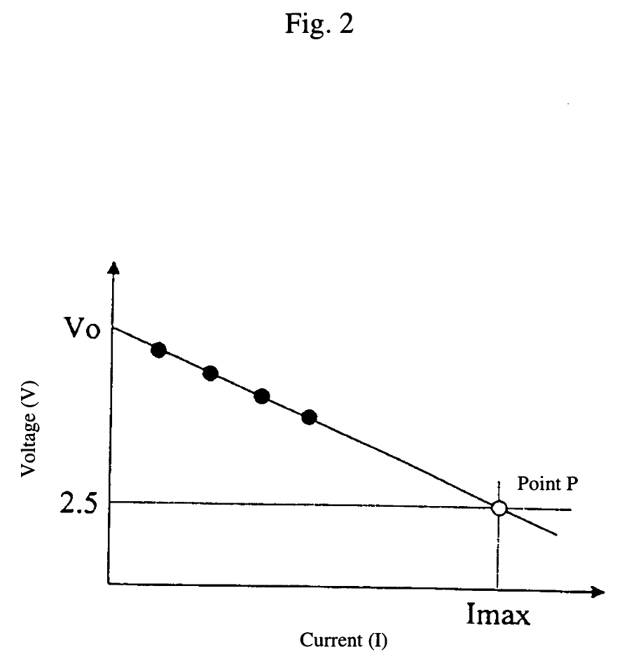

FIG. 2 is a graph showing the relationship between the current and the voltage obtained for the lithium secondary battery. From FIG. 2, the direct-current resistance (DCR) concerned was derived, and the maximum available output power at a predetermined voltage was obtained. More specifically, in the derivation of the output power, at the beginning the battery was charged until a predetermined voltage V1 was reached, and then battery was discharged for 20 sec at a current of 200 mA, 1 A, 2 A, 5 A and 8 A, and thus the values at a discharging time of 1 sec were measured. The DCR value at the voltage of V1 was obtained from the slope of the line of FIG. 2, the maximum allowable voltage was set at 2.5 V, the maximum available current value Imax was determined as the current value at 2.5 V on this line, and thus the output power Pₘₐₓ was derived on the basis of the following formula:
Pₘₐₓ=(Iₘₐₓ)×(Vₒ)
wherein Vₒ is the extrapolated intersection point of the I-V plot and corresponds to the open circuit voltage.

### COMPARATAIVE EXAMPLE 1

In Comparative Example 1, as the positive electrode, only the same region I where the reaction accompanied by charge exchange occurs as in Example 1 was formed; for the negative electrode, the same electrode as in Example 1 was prepared; the same electrolytic solution as in Example 1 was used; and thus, the lithium secondary battery of Comparative Example 1 corresponding to a conventional lithium secondary battery was fabricated.

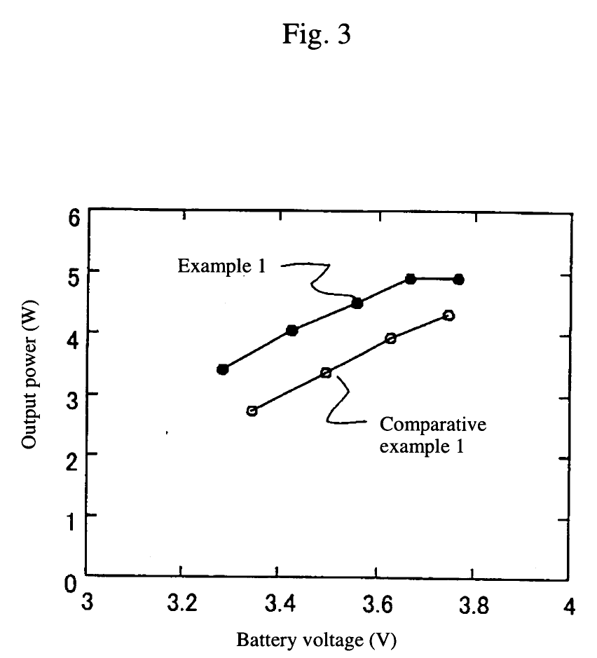

FIG. 3 is a graph showing the relationship between the output power and the battery voltage showing the output characteristics of the lithium secondary battery at −30° C. As shown in FIG. 3, the output power at 3.65 V in Example 1 was 4.89 W, but the output power at 3.65 V in Comparative Example 1 was of the order of 3.93 W. The discharge capacity of the lithium secondary battery of Comparative Example 1 was 205 mAh.

As described above, the output power at −30° C. of Example 1 was verified to be improved even by 24% as compared to that of Comparative Example 1.

### EXAMPLE 2

The positive electrode was prepared as follows: as the active material in the region I where the reaction accompanied by charge exchange occurs in the positive electrode layer 2, LiNi_{1/3}Mn_{1/3}Co_{1/3}O₂ was used; as the conducting aid, a 4:1 by weight mixture of a graphite carbon having an average particle size of 3 μm and a specific surface area of 13 m²/g and a carbon black having an average particle size of 0.04 μm and a specific surface area of 40 m²/g was used; as a material forming the region II where the charge adsorbing/desorbing reaction occurs, an activated carbon having a relatively higher specific surface area of 2000 m²/g was used; a positive electrode material paste was prepared with NMP as the solvent so as for the ratio between LiNi_{1/3}Mn_{1/3}Co1/3O₂, the conducting aid, the activated carbon and the binder PVDF to be 77:5:10:8 in the solid content ratio by weight; and the both sides of a current collector 1 were coated with the paste, dried and pressed to prepare the positive electrode. The same negative electrode and the same electrolytic solution as in Example 1 were used, and thus the energy storage device of Example 2 was fabricated. The specific area of the activated carbon is preferably 2000 to 5000 m²/g. The discharge capacity of this device was 197 mAh. The output power thereof at −30° C. and at 3.65 V was 4.76 W, to be higher even by 21% than in Comparative Example 1. Here, the positive electrode was formed with the region I and the region II mixed with each other, but the positive electrode may also be obtained by forming the region I and the region II alternately in predetermined areas on the surface of the positive electrode current collector 1.

### EXAMPLE 3

The energy storage device of Example 3 was fabricated with the same electrode configuration as in Example 1 and with an electrolytic solution prepared by dissolving LiPF₆ in a concentration of 1 M in a 3:3:1 by volume solvent mixture of EC, EMC and methyl acetate (MA) and by adding VC in a content of 2 wt %. The discharge capacity was 225 mAh, and the output power at −30° C. and at 3.65 V was 4.97 W, to be higher even by 26% than in Comparative Example 1.

### EXAMPE 4

The energy storage device of Example 4 was fabricated with the same electrode configuration as in Example 1 and with an electrolytic solution prepared by dissolving LiPF₆ in a concentration of 1 M in a 3:3:1 by volume solvent mixture of EC, EMC and methyl acetate (MA) and by adding VC in a content of 2 wt % and by further adding LiB[OCOCF₃]₄ in a content of 0.2 wt %. The discharge capacity was 222 mAh, and the output power at −30° C. and at 3.65 V was 5.15 W, to be higher even by 31% than in Comparative Example 1.

### EXAMPLE 5

The energy storage device of Example 5 was fabricated with the same electrode configuration as in Example 1 and with an electrolytic solution prepared by dissolving LiPF₆ in a concentration of 1 M in a 3:3:3:1 by volume solvent mixture of EC, DMC, EMC and methyl acetate (MA) and by adding VC in a content of 2 wt %. The discharge capacity was 230 mAh, and the output power at −30° C. and at 3.65 V was 5.05 W, to be higher even by 28% than in Comparative Example 1.

### EXAMPLE 6

The energy storage device of Example 6 was fabricated with the same electrode configuration as in Example 1 and with an electrolytic solution prepared by dissolving LiPF₆ in a concentration of 1 M in a 3:3:3:1 by volume solvent mixture of EC, γ-butyrolactone (GBL), EMC and methyl acetate (MA) and by adding VC in a content of 2 wt %. The discharge capacity was 215 mAh, and the output power at −30° C. and at 3.65 V was 5.21 W, to be higher even by 32% than in Comparative Example 1.

### EXAMPLE 7

The energy storage device of Example 7 was fabricated with the same electrode configuration as in Example 1 and with an electrolytic solution prepared by dissolving LiPF₆ in a concentration of 1 M in a 3:2:3:1:1 by volume solvent mixture of EC, γ-butyrolactone (GBL), EMC, methyl acetate (MA) and methyl nonafluorobutyl ether (MFE) and by adding VC in a content of 2 wt %. The discharge capacity of ED7 was 224 mAh, and the output power at −30° C. and at 3.65 V was 5.21 W, to be higher even by 33% than in Comparative Example 1.

### EXAMPLE 8

The energy storage device ED8 of Example 8 was fabricated with the same electrode configuration as in Example 1 and with an electrolytic solution prepared by dissolving LiPF₆ in a concentration of 1 M in a 3:5:1:1 by volume solvent mixture of EC, EMC, methyl acetate (MA) and 1,1,2,2,3,3,4-heptafluorocyclopentane (HFCP) and by adding VC in a content of 2 wt %. The discharge capacity was 214 mAh, and the output power at −30° C. and at 3.65 V was 5.21 W, to be higher even by 32% than in Comparative Example 1.

### EXAMPLE 9

The energy storage device of Example 9 was fabricated with the same electrode configuration as in Example 1 and with an electrolytic solution prepared by dissolving LiPF₆ in a concentration of 1 M in a 3:5:1:1 by volume solvent mixture of EC, EMC, methyl acetate (MA) and 1,1,2,2,3,3,4-heptafluorocyclopentane (HFCP) and by adding VC in a content of 2 wt %. The discharge capacity was 214 mAh, and the output power at −30° C. and at 3.65 V was 5.21 W, to be higher even by 32% than in Comparative Example 1.

### EXAMPLE 10

The energy storage device of Example 10 was fabricated with the same electrode configuration as in Example 1 and with an electrolytic solution prepared by dissolving LiPF₆ in a concentration of 1 M in a 3:3:3:1 by volume solvent mixture of EC, DMC, EMC and ethyl acetate (EA) and by adding VC in a content of 2 wt %. The discharge capacity was 222 mAh, and the output power at −30° C. and at 3.65 V was 4.98 W, to be higher even by 26% than in Comparative Example 1.

### EXAMPLE 11

The energy storage device of Example 11 was fabricated with the same electrode configuration as in Example 1 and with an electrolytic solution prepared by dissolving LiPF₆ in a concentration of 1 M in a 3:3:3:1 by volume solvent mixture of EC, DMC, EMC and methyl propionate (PM) and by adding VC in a content of 2 wt %. The discharge capacity was 226 mAh, and the output power at −30° C. and at 3.65 V was 5.11 W, to be higher even by 30% than in Comparative Example 1.

### EXAMPLE 12

The energy storage device of Example 12 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding vinylethylene carbonate (VEC) in a content of 2 wt %. The discharge capacity was 228 mAh, and the output power at −30° C. and at 3.65 V was 5.09 W, to be higher even by 29% than in Comparative Example 1.

### EXAMPLE 13

The energy storage device of Example 13 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and further adding anisole (AN) in a content of 3 wt %. The discharge capacity was 221 mAh, and the output power at −30° C. and at 3.65 V was 5.05 W, to be higher even by 28% than in Comparative Example 1.

### EXAMPLE 14

The energy storage device of Example 14 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and further adding 2-fuoroanisole (FAN) in a content of 3 wt %. The discharge capacity was 218 mAh, and the output power at −30° C. and at 3.65 V was 5.02 W, to be higher even by 28% than in Comparative Example 1.

### EXAMPLE 15

The energy storage device of Example 15 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and further adding terphenyl in a content of 3 wt %. The discharge capacity was 211 mAh, and the output power at −30° C. and at 3.65 V was 4.97 W, to be higher even by 26% than in Comparative Example 1.

### EXAMPLE 16

The energy storage device of Example 16 was fabricated with the same electrode configuration as in Example 1 and with an electrolytic solution prepared by dissolving LiPF₆ in a concentration of 1 M in a 3:3:3:1 by volume solvent mixture of EC, DMC, EMC and GBL and by adding VC in a content of 2 wt %. The discharge capacity was 211 mAh, and the output power at −30° C. and at 3.65 V was 5.01 W, to be higher even by 27% than in Comparative Example 1.

### EXAMPLE 17

The energy storage device of Example 17 was fabricated with the same electrode configuration as in Example 1 and with an electrolytic solution prepared by dissolving LiPF₆ in a concentration of 1 M in a 3:3:3:1 by volume solvent mixture of EC, DMC, EMC and ethylene sulfite (ES) and by adding VC in a content of 2 wt %. The discharge capacity was 226 mAh, and the output power at −30° C. and at 3.65 V was 5.07 W, to be higher even by 29% than in Comparative Example 1.

### EXAMPLE 18

The energy storage device of Example 18 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and further adding ES in a content of 2 wt %. The discharge capacity was 231 mAh, and the output power at −30° C. and at 3.65 V was 5.02 W, to be higher even by 27% than in Comparative Example 1.

### EXAMPLE 19

The energy storage device of Example 19 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and further adding propane sultone (PS) in a content of 2 wt %. The discharge capacity was 235 mAh, and the output power at −30° C. and at 3.65 V was 5.09 W, to be higher even by 29% than in Comparative Example 1.

### EXAMPLE 20

The energy storage device of Example 20 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and propane sultone (PS) in a content of 2 wt %, and further adding diphenyl disulfide (DDS) in a content of 2 wt %. The discharge capacity was 223 mAh, and the output power at −30° C. and at 3.65 V was 5.02 W, to be higher even by 27% than in Comparative Example 1.

### EXAMPLE 21

The energy storage device of Example 21 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and propane sultone (PS) in a content of 2 wt %, and further adding pyridine (PN) in a content of 2 wt %. The discharge capacity was 239 mAh, and the output power at −30° C. and at 3.65 V was 5.12 W, to be higher even by 30% than in Comparative Example 1.

### EXAMPLE 22

The energy storage device of Example 22 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and propane sultone (PS) in a content of 2 wt %, and further adding 2-methoxy-pyridine (MePN) in a content of 2 wt %. The discharge capacity was 236 mAh, and the output power at −30° C. and at 3.65 V was 5.13 W, to be higher even by 30% than in Comparative Example 1.

### EXAMPLE 23

The energy storage device of Example 23 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and further adding chain hexamethoxytriphosphazene (HFTH) in a content of 2 wt %. The discharge capacity was 236 mAh, and the output power at −30° C. and at 3.65 V was 5.04 W, to be higher even by 28% than in Comparative Example 1.

### EXAMPLE 24

The energy storage device of Example 24 was fabricated with the same electrode configuration as in Example 1 and with an electrolytic solution prepared by dissolving LiPF₆ in a concentration of 1 M in a 3:3:3:1 by volume solvent mixture of EC, DMC, EMC and MA and by adding VC in a content of 2 wt % and further adding cyclic hexamethoxytriphosphazene (cHFTH) in a content of 2 wt %. The discharge capacity was 231 mAh, and the output power at −30° C. and at 3.65 V was 5.02 W, to be higher even by 27% than in Comparative Example 1.

### EXAMPLE 25

The energy storage device of Example 25 was fabricated with the same electrode configuration as in Example 1 and with an electrolytic solution prepared by dissolving LiPF₆ in a concentration of 1 M in a 3:3:2:1:1 by volume solvent mixture of EC, DMC, EMC, MA and trimethyl phosphate (TMP) and by adding VC in a content of 2 wt %. The discharge capacity was 227 mAh, and the output power at −30° C. and at 3.65 V was 4.96 W, to be higher even by 26% than in Comparative Example 1.

### EXAMPLE 26

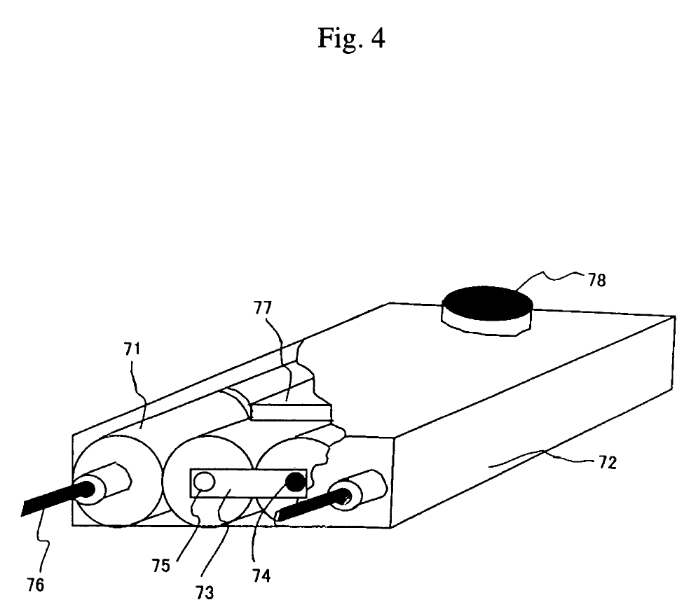

FIG. 4 is an oblique perspective view showing an energy storage device module fabricated with a plurality of the energy storage devices according to the present invention. The energy storage devices 71 were the ones fabricated in Example 1; 24 of the energy storage devices 71 were connected in series and put in a rectangular box-shaped resin container 72. Copper plates 73 of 2 mm in thickness were used to connect the individual energy storage devices 91 to each other; each of the cooper plates 73 was screwed to the positive electrode terminal 74 of one of the energy storage devices 71 and to the negative electrode terminal 75 of another one of the energy storage devices 71 so as to connect these energy storage devices. The charge/discharge current of the module is input/output through cables 76. Each of the energy storage devices 71 is connected to a control circuit 77 through a signal wire, so that the voltage and temperature of each of the energy storage devices 71 can be monitored in the course of charging/discharging. The module is provided with a vent hole 78 for cooling. In this module, the maximum terminal voltage between the terminal 76 and the terminal 79 was 98 V. This module generated an output power of 115 W at −30° C. for an SOC of 50%, and hence is excellent in the input/output characteristics at low temperatures, also providing an energy storage device module having a high energy density.

### EXAMPLE 27

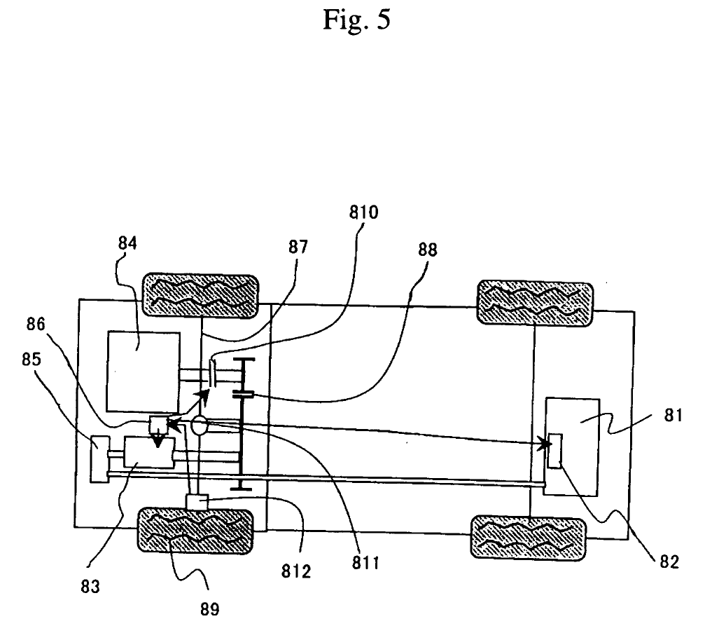

FIG. 5 is an underside front view of a hybrid electric vehicle fabricated by mounting two energy storage device modules and an internal combustion engine. As the energy storage device modules 81, the energy storage device modules according to Example 26 were used, which are connected to a module control circuit 82 so as to be controlled. The hybrid vehicle is controlled by a motive power control circuit (hybrid controller; HEVCON) 86 with respect to the running and the energy utilization efficiency. HEVCON 86 controls an internal combustion engine 84, an inverter 85, a drive motor 83 and a module control circuit 82 in such a way that the input/output for each of these members is controlled according to the running conditions. The motive power controlled by HEVCON 86 is transmitted to drive wheels 89 through a drive shaft 87, a differential gear 88, a clutch 811 and a clutch gear 812.

The running conditions are transmitted to HEVCON 86 by a speed monitor 812 and the like. When the vehicle is started, the electric power of the energy storage device modules 81 is transformed into alternating-current electric power through the inverter 85, and thereafter input into the drive motor 83 so as to drive the drive motor 83. The drive motor 83 rotates the drive wheels 89, and the vehicle can be thereby driven. According to the signals from HEVCON 86, the module control circuit 82 makes electric power be transferred from the energy storage device modules 81 to the drive motor 83. When the car speed exceeds 20 km/h during running by means of the drive motor 83, a signal is emitted from the motive power control circuit 86 to link the clutch 810 so as to crank the engine 84 by using the rotation energy from the drive wheels 89. HEVCON 86 weighs up the signals from the car speed monitor 812 and the condition of pushing down the accelerator, and the power supply to the drive motor 83 is thereby regulated, so that the number of rotations of the engine 84 can be regulated by the drive motor 83. When the car speed is a reduced value, the drive motor 83 operates as an electric generator to regenerate electric power into the energy storage device module 81. The energy storage device modules according to the present invention can be made light in weight, and hence can improve the gas mileage of hybrid vehicles.

In this Example, a hybrid vehicle with an internal combustion engine mounted thereon is adopted, but a hybrid vehicle with a fuel cell mounted thereon in place of the internal combustion engine can also be adopted. In that case, the parts associated with the internal combustion engine such as an engine and the like come to be unnecessary. The energy storage device module of the present invention can also be embodied as power supplies for mobile objects such as pure electric vehicles and golf carts exclusively using energy storage device modules as power supplies. It is to be noted that the energy storage device module of the present invention is particularly excellent in the input/output characteristics at low temperatures so as to generate high output power at −30° C. for an SOC of 50%.

### EXAMPLE 28

In this Example, the energy storage devices described in Examples 1 to 26 and the modules using these devices are applicable to the following power supplies and are particularly excellent in the input/output characteristics at low temperatures so as to generate high output power at −30° C. for an SOC of 50%: power supplies for various types of portable information-communication equipment such as personal computers, word processors, cordless handsets, electronic book players, cellular phones, car phones, pagers, handy terminals, transceivers and portable radios; power supplies for various types of portable equipment such as portable copiers, electronic organizers, electronic calculators, liquid crystal television sets, radios, tape recorders, headphone stereos, portable CD players, video movie players, electric shavers, electronic translators, voice encoders and memory cards; electronic power supplies for household electric appliances such as refrigerators, air conditioners, televisions, stereos, water heaters, electric microwave ovens, dishwashers, dryers, washers, lighting apparatuses and toys; and furthermore, power supplies for industrial applications including medical instruments, electric power storage systems and elevators. Furthermore, the energy storage devices are particularly excellent in the input/output characteristics at low temperatures so as to generate high output power at −30° C. for an SOC of 50%.

What is claimed is:

1. An energy storage device comprising:
a positive electrode having a region where a reaction accompanied by charge exchange occurs;
a negative electrode having a region where a reaction accompanied by charge exchange occurs;
a separator electrically separating said positive and negative electrodes from each other and allowing mobile ions to pass therethrough;
an electrolytic solution having an aprotic nonaqueous solvent comprising said mobile ions; and
a region in at least one of said positive and negative electrodes where a charge adsorbing/desorbing reaction occurs.

2. The energy storage device according to claim 1, wherein:
said regions where the reaction accompanied by charge exchange occurs are formed in a laminated manner in current collectors; and
said region where the charge adsorbing/desorbing reaction occurs is formed in a laminated manner on the surface of said region where the reaction accompanied by charge exchange occurs.

3. The energy storage device according to claim 1, wherein said region where the reaction accompanied by charge exchange occurs and said region where the charge adsorbing/desorbing reaction occurs are formed on the surfaces of the current collectors in a mixed manner or in an alternate manner.

4. The energy storage device according to claim 1, wherein said nonaqueous solvent comprises at least one solvent selected from the group consisting of solvents represented by the following formulas (1) to (20):
a cyclic carbonate solvent represented by: 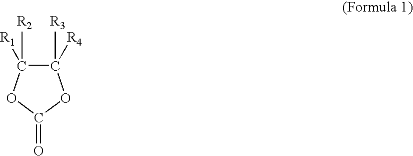
wherein R₁, R₂, R₃ and R₄ each represent a hydrogen, fluorine or chlorine atom; or alternatively a C₁₋₃ alkyl group, an allyl group or an acyl group; or alternatively a fluorinated alkyl, allyl or acyl group; and R₁, R₂, R₃ and R₄ may be the same or different from each other;
a chain carbonate solvent represented by: 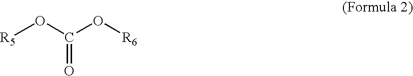
wherein R₅ and R₆ each represent a hydrogen, fluorine or chlorine atom; or alternatively a C₁₋₃ alkyl group or a fluorinated alkyl group; and R₅ and R₆ may be the same or different from each other;
a chain ester solvent represented by: 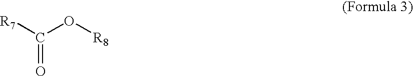
wherein R₇ and R₈ each represent a hydrogen, fluorine or chlorine atom; or alternatively a C₁₋₃ alkyl group or a fluorinated alkyl group; and R₇ and R₈ may be the same or different from each other;
a lactone derivative represented by: 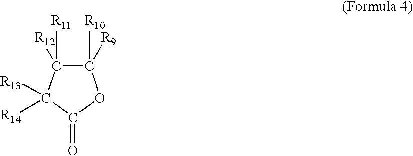
wherein R₉, R₁₀, R₁₁, R₁₂, R₁₃ and R₁₄ each represent a hydrogen, fluorine or chlorine atom; or alternatively a C₁₋₃ alkyl group; or alternatively a fluorinated alkyl, allyl or acyl group; and R₉, R₁₀, R₁₁, R₁₂, R₁₃ and R₁₄ may be the same or different from each other;
a dioxolane derivative represented by: 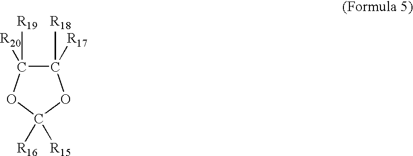
wherein R₁₅, R₁₆, R₁₇, R₁₈, R₁₉ and R₂₀ each represent a hydrogen, fluorine or chlorine atom; or alternatively a C₁₋₃ alkyl group or a fluorinated alkyl group; and R₁₅, R₁₆, R₁₇, R₁₈, R₁₉ and R₂₀ may be the same or different from each other;
a chain ether derivative represented by: 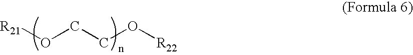
wherein n is an integer of 1 to 10, R₂₁ is methylene, and R₂₂ is a hydrogen, fluorine or chlorine atom; or alternatively a C₁₋₃ alkyl group or a fluorinated alkyl group;
a dioxolane derivative represented by: 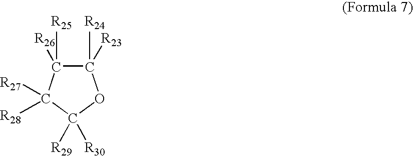
wherein R₂₃, R₂₄, R₂₅, R₂₆, R₂₇, R₂₈, R₂₉ and R₃₀ each represent a hydrogen, fluorine or chlorine atom; or alternatively a C₁₋₃ alkyl group or a fluorinated alkyl group; and R₂₃, R₂₄, R₂₅, R₂₆, R₂₇, R₂₈, R₂₉ and R₃₀ may be the same or different from each other;
a chain ether derivative represented by: 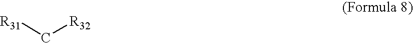
wherein n is an integer of 1 to 10, R₃₁ and R₃₂ each represent a hydrogen, fluorine or chlorine atom; or alternatively a C₁₋₃ alkyl group or a fluorinated alkyl group; and R₃₁ and R₃₂ may be the same or different from each other;
a cyclopentane derivative represented by: 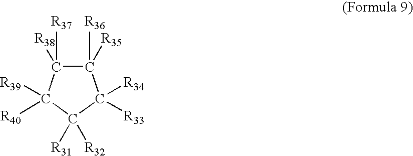
wherein R₃₁, R₃₂, R₃₃, R₃₄, R₃₅, R₃₆, R₃₇, R₃₈, R₃₉ and R₄₀ each represent a hydrogen, fluorine or chlorine atom; or alternatively a C₁₋₃ alkyl group or a fluorinated alkyl group; and R₃₁, R₃₂, R₃₃, R₃₄, R₃₅, R₃₆, R₃₇, R₃₈, R₃₉ and R₄₀ may be the same or different from each other;
an alkane represented by:
R₄₁—R₄₂ (Formula 10)
wherein R₄₁ and R₄₂ each represent a hydrogen, fluorine or chlorine atom; or alternatively a C₁₋₃ alkyl group or a fluorinated alkyl group; and R₄₁ and R₄₂ may be the same or different from each other;
a 1,3-dioxo-4,5-1en-2-one derivative represented by: 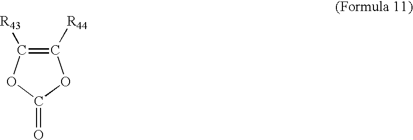
wherein R₄₃ and R₄₄ each represent a hydrogen, fluorine, chlorine atom; or alternatively a C₁₋₃ alkyl group or a fluorinated alkyl group; and R₄₃ and R₄₄ may be the same or different from each other;
a phenyl derivative represented by: 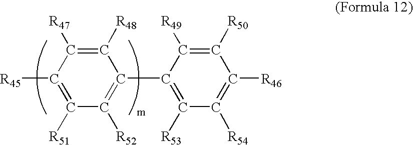
wherein R₄₅, R₄₆, R₄₇, R₄₈, R₄₉, R₅₀, R₅₁, R₅₂, R₅₃ and R₅₄ each represent a hydrogen, fluorine or chlorine atom; or alternatively a C₁₋₃ alkyl group or a fluorinated alkyl group; and R₄₅, R₄₆, R₄₇, R₄₈, R₄₉, R₅₀, R₅₁, R₅₂, R₅₃ and R₅₄ may be the same or different from each other;
an ethylene sulfite derivative represented by: 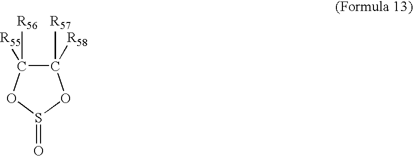
wherein R₅₅, R₅₆, R₅₇ and R₅₈ each represent a hydrogen, fluorine or chlorine atom; or alternatively a C₁₋₃ alkyl group, an allyl group or an acyl group; or alternatively a fluorinated alkyl, allyl or acyl group; and R₅₅, R₅₆, R₅₇ and R₅₈ may be the same or different from each other;
a propane sultone derivative represented by 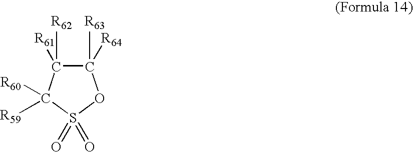
wherein R₅₉, R₆₀, R₆₁, R₆₂, R₆₃ and R₆₄ each represent a hydrogen, fluorine or chlorine atom; or alternatively a C₁₋₃ alkyl group, an allyl group or an acyl group; or alternatively a fluorinated alkyl, allyl or acyl group; and R₅₉, R₆₀, R₆₁, R₆₂, R₆₃ and R₆₄ may be the same or different from each other;
a disulfide derivative represented by
R₆₅—S—S—R₆₆ (Formula 15)
wherein R₆₅ and R66 each represent a hydrogen, fluorine or chlorine atom; or alternatively a C₁₋₃ alkyl group, an allyl group or an acyl group; or alternatively a fluorinated alkyl, allyl, acyl, phenyl, benzyl, diphenyl or terphenyl group; or alternatively a partially fluorinated phenyl, benzyl, diphenyl or terphenyl group; or alternatively a partially alkylated, allylated or acylated phenyl, benzyl, diphenyl or terphenyl group; and R₆₅ and R₆₆ may be the same or different from each other;
a benzene derivative represented by: 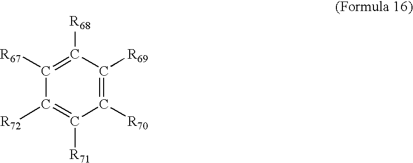
wherein R₆₇, R₆₈, R₆₉, R₇₀, R₇₁ and R₇₂ each represent a hydrogen, fluorine or chlorine atom; or alternatively a C₁₋₃ alkyl group, an allyl group, an acyl group or an alkoxy group; or alternatively a fluorinated alkyl, allyl, acyl or alkoxy group; and R₆₇, R₆₈, R₆₉, R₇₀, R₇₁, and R₇₂ may be the same or different from each other;
a pyridine derivative represented by: 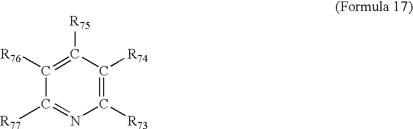
wherein R₇₃, R₇₄, R₇₅, R₇₆ and R₇₇ each represent a hydrogen, fluorine or chlorine atom; or alternatively a C₁₋₃ alkyl group, an allyl group, an acyl group or an alkoxy group; or alternatively a fluorinated alkyl, allyl, acyl or alkoxy group; and R₇₃, R₇₄, R₇₅, R₇₆ and R₇₇ may be the same or different from each other;
a chain phosphazene derivative represented by: 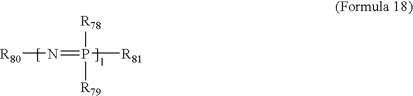
wherein R₇₈, R₇₉, R₈₀ and R₈₁ each represent a C₁₋₃ alkyl group, an allyl group, an acyl group or an alkoxy group; or alternatively a fluorinated alkyl, allyl, acyl or alkoxy group; and R₇₈, R₇₉, R₈₀ and R₈₁ may be the same or different from each other;
a cyclic phosphazene derivative represented by: 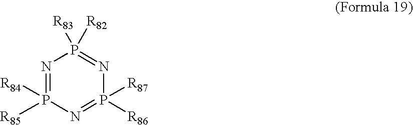
wherein R₈₂, R₈₃, R₈₄, R₈₅, R₈₆ and R₈₇ each represent a C₁₋₃ alkyl group, an allyl group, an acyl group or an alkoxy group; or alternatively a fluorinated alkyl, allyl, acyl or alkoxy group; and R₈₂, R₈₃, R₈₄, R₈₅, R₈₆ and R₈₇ may be the same or different from each other;
and a phosphate derivative represented by: 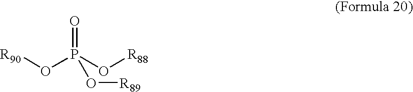
wherein R₈₈, R₈₉ and R₉₀ each represent a C₁₋₃ alkyl group or a fluorinated alkyl group; and R₈₈, R₈₉ and R₉₀ may be the same or different from each other.

5. The energy storage device according to claim 1, wherein said region where the reaction accompanied by charge exchange occurs in said positive electrode comprises at least one electric energy storing/releasing material selected from the group consisting of LiNiₓMn_{y}Co_{z}O₂ (with the proviso that x+y+z=1), a composite oxide comprising Li and one or more transition metals such as Co, Ni, Mn and Fe, and an olivine-structured phosphate compound represented by LiMePO₄ (Me being Fe, Co or Cr).

6. The energy storage device according to claim 1, wherein, said region where the reaction accompanied by charge exchange occurs in said negative electrode comprises at least one electric energy storing/releasing material selected from the group consisting of a carbonaceous material capable of occluding/releasing lithium; lithium metal; a lithium alloy; silicon; silicon oxides; tin; tin oxides; and composite materials composed of the carbonaceous material and one or more of lithium metal, a lithium alloy, silicon, silicon oxides, tin and tin oxides.

7. The energy storage device according to claim 1, wherein said region where the charge adsorbing/desorbing reaction occurs comprises at least one selected from the group consisting of activated carbon, carbon nanotube, expanded graphite, ruthenium oxide, titanium oxide, and composite materials composed of the activated carbon and one or more of carbon nanotube, expanded graphite, ruthenium oxide and titanium oxide.

8. The energy storage device according to claim 1, wherein said electrolytic solution comprises at least one solute selected from the group consisting of LiPF₆, LiAsF₆, LiBF₄, LiSO₂CF₃, LiN[SO₂CF₃]₂, LiN[SO₂CF₂CF₃]₂, LiC[SO₂CF₃]₃, LiC[SO₂CF₂CF₃]₂, LiB[OCOCF₃]₄, LiB[OCOCF₂CF₃]₄, LiI, LiBr, LiCl, NaPF₆, NaAsF₆, NaBF₄, NaSO₂CF₃, NaN[SO₂CF₃]₂, NaN[SO₂CF₂CF₃]₂, NaC[SO₂CF₃]₃, NaC[SO₂CF₂CF₃]₂, NaB[OCOCF₃]₄, NaB[OCOCF₂CF₃]₄, Nal, NaBr and NaCl.

9. The energy storage device according to claim 1, wherein said electrolytic solution comprises at least one selected from the group consisting of ethylene carbonate (EC), propylene carbonate (PC) and butylene carbonate (BC), at least one selected from the group consisting of dimethyl carbonate (DMC), ethyl methyl carbonate (EMC) and diethyl carbonate (DEC), and at least one selected from the group consisting of LiPF_{6, LiBF}_{4, LiSO}_{2CF}_{3, LiN[SO}₂CF₃]₂, LiN[SO₂CF₂CF₃]₂, LiC[SO₂CF₃]₃, LiC[SO₂CF₂CF₃]₂, LiB[OCOCF₃]₄ and LiB[OCOCF₂CF₃]₄.

10. The energy storage device according to claim 9, wherein said electrolytic solution comprises at least one selected from the group consisting of methyl acetate (MA), ethyl acetate (EA), methyl propionate (MP) and ethyl propionate (ME).

11. The energy storage device according to claim 9, wherein said electrolytic solution comprises at least one selected from the group consisting of nonafluorobutyl methyl ether, nonafluorobutyl ethyl ether and heptafluorocyclopentane.

12. The energy storage device according to claim 9, wherein said electrolytic solution comprises at least one selected from the group consisting of vinylene carbonate, ethylene sulfide, propane sultone, diphenyl disulfide, methoxybenzene, methoxypyridine and hexamethylcyclophosphazene.

13. A secondary battery which is a coin-shaped or cylindrical battery comprising the energy device according to claim 1.

14. A redox capacitor comprising the energy device according to claim 1.

15. An energy device module comprising a plurality of the energy storage devices according to claim 1 connected to each other in series, in parallel, or in series-parallel, and a control circuit for controlling at least any one of the current and the voltage of an electric circuit formed by said connection.

16. An electric vehicle comprising the energy storage device module according to claim 15 mounted therein and an electric motor driven by the power supplied by said module.

17. A hybrid vehicle comprising the energy storage device module according to claim 15 mounted therein, and an electric motor driven by the power supplied by said module and an internal combustion engine.
